(19) United States
(12) Patent Application Publication
(10) Pub. No.: US 2017/0318699 A1
(43) Pub. Date: Nov. 2, 2017

(54) HOUSING

(71) Applicant: Eaton Protection Systems IP GmbH & Co. KG, Schönefeld (DE)

(72) Inventors: Toni Ott, Neckargemünd (DE); Reiner Naumann, Mannheim (DE)

(73) Assignee: Eaton Protection Systems IP GmbH & Co. KG, Schönefeld (DE)

(21) Appl. No.: 15/526,255

(22) PCT Filed: Nov. 9, 2015
(86) PCT No.: PCT/EP2015/076050

§ 371 Date: May 11, 2017

(30) Foreign Application Priority Data
Nov. 12, 2014 (DE) 10 2014 016 742.9

(51) Int. Cl. H05K 5/02; B65D 81/02; H05K 7/20; B65D 85/42; H02G 3/03; H02B 1/56; H02G 3/08; H05K 5/00; H02B 1/46

(52) U.S. Cl. CPC H05K 5/0217; B65D 85/42; B65D 81/022; H05K 7/20418; H02B 1/46; H02B 1/56; H02G 3/081; H05K 5/0017; H02G 3/03

(57) ABSTRACT

The present invention relates to a housing of an electric/electronic equipment, such as a luminaire, terminal box, control device, switching distributor or the like, comprising at least one lateral surface facing the surroundings. In order to improve a housing of said type in such a way that a sufficient strength of the housing is given, even with a comparatively small material thickness, and such that also additional measures for cooling can be dispensed with, a plurality of impact dampers that protrude at least from the lateral surface are arranged on said lateral surface.

The present invention relates to a housing of an electric/electronic equipment. Such equipment comprises e.g. luminaires, terminal boxes, control devices, switching distributors or the like.

Equipment of this type may also be used in explosion-prone areas. Such a housing comprises at least one lateral surface facing the surroundings.

As has already been stated, such housings are adapted for use in explosion-prone areas and should be able to resist also shocks that may come from outside. In order to allow testing of the shock resistance of such a housing, there are predetermined test conditions according to IEC 60079 for shock testing, in the case of which e.g. impact energies of the order of 4 J, 7 J, 20 J, or the like, are applied for examining the stability of the housing. For guaranteeing a sufficient shock resistance of the housing, the latter has, up to now, been produced from a suitable material, such as aluminum, polyester (may also be glass fiber reinforced, if necessary), polyamide or the like. A certain material thickness is here usually necessary for passing the shock test.

The known housings are disadvantageous insofar as a suitable material thickness has to be used, which makes the housing more expensive and heavier. In addition, said material thickness makes it more difficult to discharge heat produced within the housing, so that additional or sufficiently dimensioned cooling units are required.

It is the object of the present invention to improve a housing of the type referred to at the beginning such that a sufficient strength of the housing will be given even with a comparatively small material thickness and such that also additional measures for cooling can be dispensed with.

This object is achieved by the features of claim 1. In particular, the present invention is characterized in that a plurality of impact dampers that protrude from the lateral surface are arranged on said lateral surface. In the case of respective blows or during the shock test described, an impact on one or a plurality of these impact dampers takes place. The latter protrude from the lateral surface and absorb most of the resultant impact energy. The transmission of impact energy directly to respective lateral surfaces of the housing or to electric/electronic units within the housing is thus substantially reduced.

Damage to the housing or to parts arranged therein is avoided in this way.

The impact dampers according to the present invention additionally have the advantage that they can also be used at low ambient temperatures. Otherwise, in particular plastic materials, which may become more brittle at low temperatures, would have to be configured with a larger material thickness or with additional reinforcing means within the housing.

Taking all this into account, a simple and cost-efficient measure is obtained according to the present invention, which guarantees the shock resistance of a housing of the type in question, irrespectively of the temperature, the wall thickness of said housing being reduced at the same time.

In order to be able to protect the respective lateral surface with impact dampers across the whole area thereof, said impact dampers may be configured in a rib-like or fin-like manner. It is also imaginable that each impact damper is configured as a single element and that a plurality of said impact dampers are arranged e.g. in rows and/or columns on the lateral surface.

The use of such rib-like or fin-like impact dampers also leads to an increased strength for the housing and especially the respective wall surface or lateral surface, so that the material strength of this wall and of the housing, respectively, can possibly be reduced still further. According to a simple embodiment, each of the impact dampers may have the same cross-section. An imaginable cross-section is e.g. an acute-angled triangle, a rectangular shape, a frustoconical cross-section or the like. Housings of the type in question may also be arranged side-by-side. In this case, lateral surfaces that are in contact with lateral surfaces of other housings need not have arranged thereon such impact dampers. However, the impact dampers may otherwise protrude from all lateral surfaces and in particular also in the area of connecting edges between such lateral surfaces. Also a lid of a housing may have arranged thereon impact dampers.

According to requirements, the impact dampers provided may also have different cross-sectional shapes, different thicknesses, different lengths, and they may be provided in different densities, with different orientations and/or shapes. In particular in the area of connecting edges it may prove advantageous, when the density of arrangement of such impact dampers is increased in these areas. Likewise, it may be of advantage when e.g. specific lateral surfaces, which are associated with surroundings in which shocks are more likely than in the case of other lateral surfaces, have arranged thereon e.g. impact dampers having a larger thickness and/or a larger length, and/or an increased density of impact dampers.

Normally, it also proves to be advantageous when such an impact damper protrudes perpendicularly from the respective lateral surface. The impact energy absorbed from the surroundings is thus advantageously dissipated to the housing and possibly also distributed to neighboring impact dampers.

In the case of certain arrangements of the housing or also for a suitable absorption of impact energy, it may also be considered advantageous when a respective impact damper extends such that it is inclined relative to the plane of the outer side, i.e. a respective impact damper is arranged with a certain inclination relative to the lateral surface. In addition, it is imaginable that the impact damper has a predetermined breaking point, so that, when the impact energy is sufficiently high, the impact damper will be bent or even knocked off.

The use of these impact dampers allows a reduction of the wall thickness for the housing, so that the dissipation of heat to the surroundings can be improved. In order to improve this heat dissipation still further, it is to be considered advantageous when the impact dampers can be used as cooling elements, if necessary, i.e. the impact dampers enlarge the surface of the housing and the entire enlarged surface can be used for dissipating heat to the surroundings. An additional arrangement of a cooling unit is here not necessary. In order to allow the use as cooling elements, it proves also advantageous in this connection when the impact dampers are made of a material having sufficient thermal conductivity.

For such an increased thermal conductivity as well as for an improved adaptation of the impact dampers to shocks, it may also prove advantageous when the impact dampers consist of a material that differs from the material of the housing. In this connection, it is also possible that only a few impact dampers or e.g. impact dampers that are associated with a lateral surface are made of a specific material which is e.g. different from the material of the housing and possibly also different from the material of impact dampers on other lateral surfaces. The material may also be selected such that the impact dampers are flexible for absorbing impact energy, especially when subjected to an impact test.

In order to replace impact dampers, if an impact damper should break, or in order to arrange other impact dampers having a different length, a different thickness, a different cross-section, or consisting of a different material or the like, it may additionally prove advantageous when such impact dampers are releasably attached to the lateral surface of the housing. The impact dampers can thus easily be fixed and replaced.

On the other hand, it may also be of advantage when the impact dampers are produced such that they are integral with the housing, so as to simplify production of the housing.

In order to be able to replace, if necessary, whole groups of impact dampers in the area of a lateral surface or for an entire lateral surface or the like, it may additionally be of advantage when the impact dampers are adapted to be handled and attached to the lateral surface in groups. Hence, it is e.g. not necessary to attach or release an individual impact damper, but this can be done in groups.

Especially in explosion-prone areas, such impact dampers may avoid damage to the housing, so that the housings according to the present invention may especially also be configured as explosion-proof housings.

According to an advantageous further development of the present invention, the impact dampers may have a flat portion and/or a rounding on their free end, i.e. the respective impact damper tip has a bevel or a rounding, which prevents, in case of an impact perpendicular to the housing, the force from being transmitted directly to the housing or an excessive load from being applied to the impact damper. Due to the bevel or rounding, a load impact centrally to the impact damper will be prevented, and the respective impacting body will be forced to slip off. This has the effect that the force will be distributed between neighboring impact dampers, since force will be transmitted e.g. also to neighboring impact dampers. According to an advantageous embodiment, a respective angle between the flat portion and the lateral surface of the housing may be larger than 0° and smaller than 90°. Specially preferred, this angle may be larger than 10° and smaller than 80°, and particularly preferred it may be larger than 20° and smaller than 70°. Likewise, an angle of this flat portion is ≠90° relative to a longitudinal axis of the impact damper, if the latter is straight in shape.

In the following, advantageous embodiments of the invention will be explained in more detail making reference to the enclosed figures of the drawings.

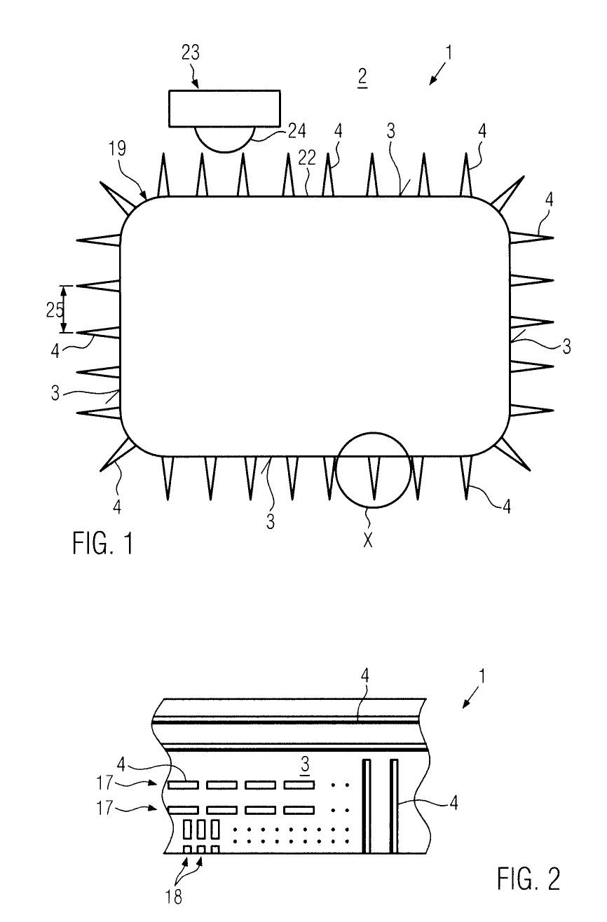

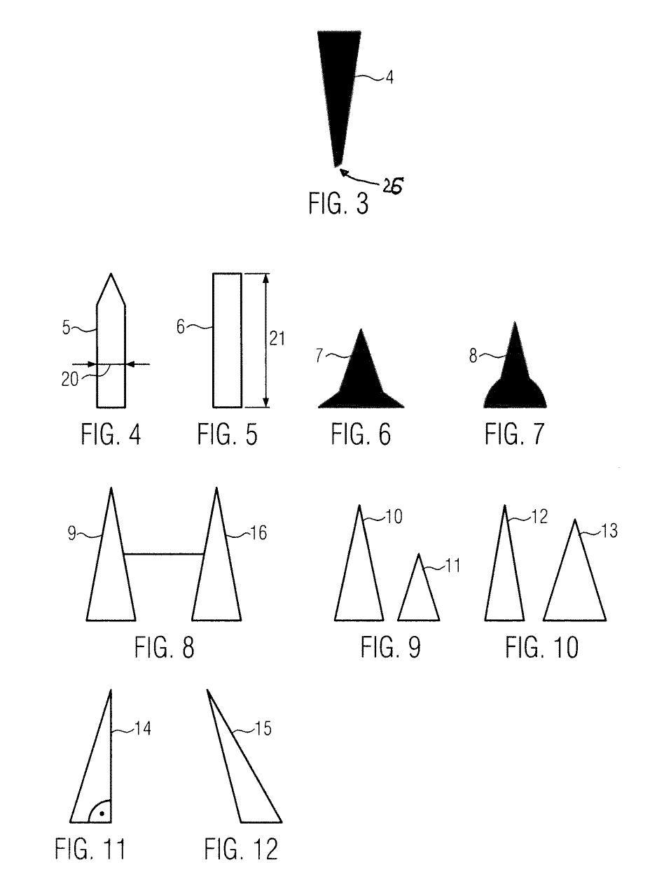

FIG. 1 shows a top view of a housing according to the present invention with a testing device;

FIG. 2 shows a top view of a further housing with different arrangements of impact dampers;

FIG. 3 shows an enlarged representation of detail “X” according to FIG. 1, and

FIGS. 4 to 12 show various embodiments of impact dampers.

FIG. 1 shows a top view of an embodiment of a housing 1 comprising a plurality of impact dampers 4. The housing 1 has an approximately rectangular cross-section with rounded connecting edges 19 between respective lateral surfaces 3. The lateral surfaces have arranged thereon impact dampers 4 protruding in the direction of the surroundings 2. These impact dampers 4 have an approximately triangular cross-section, in particular a cross-section corresponding to an acute-angled triangle. The impact dampers 4 extend perpendicular to the plane of the figure along the respective lateral surfaces 3 around the housing on all sides thereof. Corresponding impact dampers 4 may also be arranged on the upper side and/or the lower side of the housing 1. On lateral surfaces which are associated with other, neighboring housings and are in contact with the latter, or are attached to a mounting surface, no such impact dampers are provided. According to the embodiment shown in FIG. 1, the respective impact dampers 4 extend perpendicular to a plane 22 of the lateral surface 3. The impact dampers 4 are spaced apart at a distance 25, which is smaller than a respective width of a test element 24 of a testing device 23, said test element 24 being e.g. an impact ball having a diameter of 25 mm, by way of example. Such a testing device 23 is used for executing a shock test.

The impact dampers 4 in question are also used as cooling elements and they are attached to the lateral surface 3. They may be attached in a releasable manner, so that each impact damper can be removed and replaced by another one. According to another embodiment, the impact dampers may be formed integrally with the housing 1. The material of the impact dampers may differ from the material of the housing so as to configure the impact dampers e.g. such that they exhibit an improved temperature resistance, in particular with respect to cold temperatures, a suitable flexibility for absorbing impact energy, and the like.

In the case of the embodiment shown according to FIG. 1, the impact dampers are arranged in a substantially rib-like or fin-like manner and they extend along the entire lateral surface 3.

According to other embodiments, impact dampers 4 of the type in question having different shapes, different cross-sections, different orientations, different densities, different lengths and the like may be arranged. In the case of the embodiment shown, all the impact dampers have substantially the same cross-section and the same height relative to the lateral surface 3. In addition, the density of arrangement of the impact dampers is substantially constant.

FIG. 2 shows different arrangements of the impact dampers 4 on a lateral surface 3. In the upper area two rib-shaped impact dampers 4 extend over the entire width of the lateral surface 3. In the lower part, on the right-hand side, at least two rib-shaped impact dampers extend perpendicular to the above mentioned impact dampers. Additional ones of these impact dampers may be provided.

In the remaining part of FIG. 2, various individual impact dampers are shown, which are arranged in rows 17 and columns 18.

It is imaginable that all the arrangements of impact dampers shown in FIG. 2 are provided on a respective lateral surface 3. Normally, one kind of arrangement will, however, be preferred, since this will facilitate production.

In the following figures, different embodiments of an impact damper are shown. FIG. 3 represents in particular an enlarged view of detail “X” according to FIG. 1.

According to FIG. 3, the impact damper has a cross-section corresponding to an acute-angled triangle. A base of said triangle serves the purpose of mounting to the lateral surface 3 of the housing. This mounting may be of a releasable nature, or the impact damper 4 may be formed integrally with the housing 1.

In the case of the depicted embodiment of the impact damper, the latter has a flat portion 26 on its free end. This portion may also be configured as a rounding. In the case of an impact perpendicular to the housing, this flat portion or rounding will prevent a direct transmission of force to the housing or an application of an excessive load to the impact damper. Due to the flat portion or rounding, a load impact centrally to the impact damper will be prevented, and the respective impacting body will be forced to slip off towards the neighboring impact damper, i.e. the force in question will be distributed between neighboring impact dampers. Analogously, also the other embodiments of the impact damper according to the additional figures may be provided with such a flat portion or rounding.

In FIG. 3, an angle 27 between the flat portion 26 and an associated lateral surface 3 of the housing is additionally shown. This angle is larger than 0° and smaller than 90°, and preferably larger than 10° and smaller than 80°, and particularly preferred larger than 20° and smaller than 70°. The angle of the flat portion may also be defined relative to a longitudinal axis 28 of the impact damper, said angle being in this case ≠90°.

In the following FIGS. 4 to 12, different cross-sectional shapes, different orientations or also connections between neighboring impact dampers are shown.

The impact damper 5 according to FIG. 4 has an arrow-shaped cross-section with a tip at the top. A respective thickness 20 of the impact damper 5 is, except for the tip, substantially constant. Also this kind of impact dampers may be arranged on the entire outer side of the housing 1 in a rib-like or fin-like manner, cf. e.g. FIG. 2. According to requirements, also impact dampers 5 having different thicknesses 20 may be used. This applies analogously also to the other shapes of the impact dampers.

It should here be pointed out once more that impact dampers 5 may normally be arranged on all the free outer sides of the housing or on the respective lateral surfaces. Lateral surfaces which are in contact with neighboring housings may be free of such impact dampers. Likewise, also a lid which is adapted to be attached to such a housing may have impact dampers of the type in question at least on the upper side thereof. If respective lateral surfaces of the lid extend in the direction of the lateral surfaces of the housing, also these lateral surfaces of the lid may have arranged thereon impact dampers 5 of the type in question.

In FIG. 5, the impact damper 6 is substantially rectangular in cross-section and extends over a length 21. It is also possible that respective impact dampers with different lengths are arranged on a lateral surface 3. This applies again to all the various shapes of impact dampers.

Furthermore, an embodiment may be configured such that impact dampers of different shapes are arranged on an outer side or in specific areas on the outer side of the housing.

The impact damper 7 according to FIG. 6 has a triangular tip, which extends from a spherical calotte. The spherical calotte is in contact with the lateral surface.

The impact damper 8 according to FIG. 7 differs from that according to FIG. 6 insofar as the lower part thereof has a semicircular cross-section on which the respective tip is arranged.

The impact dampers 9 and 16 according to FIG. 8 are configured analogously to the impact damper 4 according to FIG. 3, these impact dampers being, however, connected to one another. Such a connection may be provided between all the impact dampers on the outer side 3 of the housing 1, or especially in the case of impact dampers in the area of connecting edges 19, cf. FIG. 1.

The impact dampers 9 and 16 according to FIG. 8 may also be configured such that they have different cross-sections, different thicknesses, different lengths and the like.

In FIG. 9 two impact dampers 10 and 11 having different heights are shown. These impact dampers may be arranged on a lateral surface 3 of a housing 1.

Analogously, also impact dampers 12, 13 according to FIG. 10 having cross-sections of different thicknesses may be arranged. The thicker impact dampers 13 may here be arranged in the area of a connecting edge 19, cf. FIG. 1. As has already been stated, all the impact dampers may also be configured such that they have different heights. This applies also with respect to FIG. 10.

FIG. 11 shows an impact damper 14 having a cross-section of a right-angled triangle, and FIG. 12 shows an impact damper 15 which extends such that it is inclined towards one side relative to the plane 22 of the outer side 3.

The embodiments shown are only of an exemplary nature. Additional cross-sectional shapes and/or combinations of impact dampers of the above described type are possible.

The impact dampers may be made of a comparatively firm material or of a flexible material. For example, the impact dampers may have predetermined breaking points, so that an impact damper will break off in response to a certain impact energy. Analogously, a flexible deformation of an impact damper or of a group of impact dampers may take place.

As has already been stated hereinbefore, each impact damper may releasably be attached to the lateral surface 3 of the housing 1. This applies analogously also to groups of impact dampers, so that the latter can be handled and attached to the lateral surface in groups.

In particular, all the depicted impact dampers and also further possible impact dampers according to the present application are adapted to be used also for explosion-proof housings 1 and/or for the purpose of cooling the housing.

Although a “housing” has always been referred to in the above text, such a housing need not be completely closed. A “housing” may e.g. also be a lid of some other housing or a part of the housing having such a lid attached thereto. Of course, impact dampers of the type in question can be attached to all the parts of such a housing, including the lid. Such a housing may also be a subhousing, a cover, a protective trough or the like, the respective electric or electronic equipment being e.g. a switching distributor, a control device, a terminal box, a luminaire or the like. The impact dampers according to the present invention have no direct influence on the protection class of the housing, so that they can be used substantially for all explosion-proof housings, irrespectively of the protection class, cf. for example ex-i, ex-e, ex-d or the like.

1. A housing (1) of an electric/electronic equipment, such as a luminaire, terminal box, control device, switching distributor or the like, comprising at least one lateral surface (3) facing the surroundings (2), characterized in that a plurality of impact dampers (4 to 16) that protrude at least from the lateral surface (3) are arranged on said lateral surface (3).

2. The housing according to claim 1, characterized in that the impact damper (4 to 16) is configured in a rib-like or fin-like manner.

3. The housing according to claim 1 or 2, characterized in that the impact dampers (4 to 16) are arranged in rows and/or columns on the lateral surface (3).

4. The housing according to one of the preceding claims, characterized in that each of the impact dampers (4 to 16) has the same cross-section.

5. The housing according to one of the preceding claims, characterized in that impact dampers (4 to 16) protrude at least from all the lateral surfaces (3) and in particular also from connecting edges between the lateral surfaces (3).

6. The housing according to one of the preceding claims, characterized in that the impact dampers (4 to 16) arranged have different cross-sections and/or thicknesses (20) and/or lengths (21) and/or densities and/or orientations and/or shapes.

7. The housing according to one of the preceding claims, characterized in that the impact damper (4 to 16) protrudes substantially perpendicularly from the lateral surface (3).

8. The housing according to one of the preceding claims, characterized in that the impact damper (4 to 16) extends such that it is inclined relative to a plane (22) of the lateral surface (3).

9. The housing according to one of the preceding claims, characterized in that the impact damper (4 to 16) has a predetermined breaking point.

10. The housing according to one of the preceding claims, characterized in that the impact damper (4 to 16) is used as a cooling element.

11. The housing according to one of the preceding claims, characterized in that the impact damper (4 to 16) consists of a material that differs from the material of the housing (1).

12. The housing according to one of the preceding claims, characterized in that the impact damper (4 to 16) is flexible, especially when subjected to an impact test.

13. The housing according to one of the preceding claims, characterized in that the impact damper (4 to 16) is releasably attached to the lateral surface (3).

14. The housing according to one of the preceding claims, characterized in that the impact damper (4 to 16) is produced such that it is integral with the housing (1).

15. The housing according to one of the preceding claims, characterized in that impact dampers (4 to 16) are adapted to be handled and attached to the lateral surface (3) in groups.

16. The housing according to one of the preceding claims, characterized in that the housing (1) is configured as an explosion-proof housing.

17. The housing according to one of the preceding claims, characterized in that the impact damper (4 to 16) has a flat portion and/or rounding (26) on its free end.

18. The housing according to one of the preceding claims, characterized in that, when the housing is subjected to an impact test according to a relevant standard, a drop test hammer hits the housing from a predetermined height of drop with a specific load energy of e.g. 4J, 7J, 20J, or the like.

19. The housing according to one of the preceding claims, characterized in that the flat portion (26) defines relative to the lateral surface (3) of the housing (1) an angle (27) of more than 0° and less than 90°, particularly of more than 10° and less than 89°, and particularly of more than 20° and less than 70°.

20. The housing according to one of the preceding claims, characterized in that the impact dampers (4) are spaced apart at a distance (25) that is smaller than a respective width of a test element (24).
